(19) United States
(12) Patent Application Publication
(10) Pub. No.: US 2014/0001551 A1
(43) Pub. Date: Jan. 2, 2014

(54) Lateral Double Diffused Metal Oxide Semiconductor Device and Manufacturing Method Thereof

(71) Applicant: Tsung-Yi Huang, Hsinchu City (TW)

(72) Inventor: Tsung-Yi Huang, Hsinchu City (TW)

(73) Assignee: Richtek Technology Corporation, R.O.C.

(21) Appl. No.: 13/538,234

(22) Filed: Jun. 29, 2012

(51) Int. Cl. H01L 29/78; H01L 21/336

(52) U.S. Cl. 257/339; 438/286; 257/E29.256; 257/E21.417

(57) ABSTRACT

The present invention discloses a lateral double diffused metal oxide semiconductor (LDMOS) device and a manufacturing method thereof. The LDMOS device is formed in a first conductive type substrate, and includes a high voltage well, a first field oxide region, at least one second field oxide region, a source, a drain, a body region, and a gate. The second field oxide region is located between the first field oxide region and the drain from top view. The distribution of the concentration of the second conductive type impurities in the high voltage well is related to the location of the second field oxide region.

### BACKGROUND OF THE INVENTION

1. Field of Invention

The present invention relates to a lateral double diffused metal oxide semiconductor (LDMOS) device and a manufacturing method thereof; particularly, it relates to such LDMOS device and a manufacturing method thereof wherein the breakdown voltage is increased.

2. Description of Related Art

FIGS. 1A-1C show a cross-section view, a 3D (3-dimensional) view, and a top view of a prior art lateral double diffused metal oxide semiconductor (LDMOS) device 100, respectively. As shown in FIGS. 1A-1C, a P-type substrate 11 has multiple isolation regions 12 by which a device region of the LDMOS device 100 is defined. The isolation regions 12 and a field oxide region 12a for example are a local oxidation of silicon (LOCOS) structure or a shallow trench isolation (STI) structure, the former being shown in the figures. The LDMOS device 100 includes an N-type well 14, a gate 13, a drain 15, a source 16, a body region 17, a body electrode 17a, and the field oxide region 12a. The well 14, the drain 15 and the source 16 are formed by lithography process steps and ion implantation process steps, wherein the lithography process step defines the implantation region by a photoresist mask together with a self-alignment effect provided by all or part of the gate 13, and the ion implantation process step implants N-type impurities to the defined region in the form of accelerated ions. The drain 15 and the source 16 are beneath the gate 13 and at different sides thereof respectively. The body region 17 and the body electrode 17a are formed by lithography process steps and ion implantation process steps, wherein the lithography process step defines the implantation region by a photoresist mask together with a self-alignment effect provided by all or part of the gate 13, and the ion implantation process step implants P-type impurities to the defined region in the form of accelerated ions. Part of the gate 13 is above the field oxide region 12a in the LDMOS device 100. The LDMOS device is a high voltage device designed for applications requiring higher operation voltages. However, for operating in the high voltage environment with a higher breakdown voltage, the conduction resistance is usually sacrificed (i.e., higher conduction resistance), and thus the application range of the LDMOS device is limited. It is a dilemma between the performance of the conduction resistance and the breakdown voltage; changing parameters of ion implantation process steps, or adding additional ion implantation process steps can reduce the conduction resistance, but the breakdown voltage will be sacrificed, or the manufacturing cost will be increased.

In view of above, to overcome the drawbacks in the prior art, the present invention proposes an LDMOS device and a manufacturing method thereof, which increases the breakdown voltage without sacrificing the conduction resistance, so that the LDMOS device may have a broader application range, in which additional manufacturing process steps are not required. Besides, the parameters of the ion implantation process steps of the high voltage LDMOS device of the present invention can be adopted in a low voltage device, i.e., the ion implantation steps of the high voltage LDMOS device and the low voltage device may be integrated, such that the high voltage LDMOS device may be integrated with a low voltage device in one substrate.

### TOTAL OF THE INVENTION

A first objective of the present invention is to provide a lateral double diffused metal oxide semiconductor (LDMOS) device.

A second objective of the present invention is to provide a manufacturing method of an LDMOS device.

To achieve the objectives mentioned above, from one perspective, the present invention provides an LDMOS device, which is formed in a first conductive type substrate, wherein the substrate has an upper surface. The LDMOS device includes: a second conductive type high voltage well, which is formed in the substrate beneath the upper surface; a first field oxide region, which is formed on the upper surface, and is located in the high voltage well from top view; a gate, which is formed on the upper surface, wherein a first part of the gate is above the first field oxide region; a second conductive type source and a second conductive type drain, which are formed beneath the upper surface at two sides of the gate respectively; a first conductive type body region, which is formed in the substrate beneath the upper surface, at the same side as the source with respect to the gate, wherein the source is located in the body region; and at least one second field oxide region, which is formed on the upper surface, and is located between the first field oxide region and the drain from top view.

From another perspective, the present invention provides a manufacturing method of an LDMOS device, including: providing a first conductive type substrate, wherein the substrate has an upper surface; forming a first field oxide region and at least one second field oxide region on the upper surface; forming a second conductive type high voltage well in the substrate beneath the upper surface, the first field oxide region and the at least one second field oxide region are within the range of the high voltage well from top view; forming a gate on the upper surface, wherein the gate includes a first part, which is above the first field oxide region; and forming a second conductive type source and a second conductive type drain beneath the upper surface at two sides of the gate respectively, and forming a first conductive type body region in the substrate beneath the upper surface, at the same side as the source with respect to the gate, wherein the source is located in the body region, and the drain is located outside the one second field oxide region or one of the second field oxide regions which is most away from the gate; wherein the high voltage well is formed after the first and second field oxide regions are formed, such that a distribution of the concentration of the second conductive type impurities in the high voltage well is related to the location of the at least one second field oxide region.

In one preferable embodiment, at least one opening region is defined between the first field oxide region and the second field oxide region, wherein a second conductive type impurity concentration beneath the upper surface at the opening region is higher than that beneath the first field oxide region and that beneath the second oxide region.

In the aforementioned embodiment, the gate may further include a second part, which is formed on the upper surface at the opening region, and has a gate dielectric layer connected to the upper surface.

In the aforementioned embodiment, the gate may further include a third part, which is formed on the second field oxide region.

In one preferable embodiment, the LDMOS device includes a plurality of second field oxide regions, wherein a plurality of opening regions are defined between the first field oxide region and its adjacent second field oxide region, and between the second field oxide regions, wherein second conductive type impurity concentrations beneath the upper surface at the opening regions are higher than those beneath the first field oxide region and the second oxide regions.

In the aforementioned embodiment, the opening region which is relatively nearer to the drain has an area preferable larger than that of the opening region which is relatively nearer to the first field oxide region.

In another embodiment, the body region and the substrate may be separated by the high voltage well, such that the body region and the substrate are not in direct contact with each other; or at least part of the body region may be directly connected to the substrate, or may be indirectly connected to the substrate by a first conductive type connecting well, such that the body region and the substrate are electrically connected.

The objectives, technical details, features, and effects of the present invention will be better understood with regard to the detailed description of the embodiments below.

### BRIEF DESCRIPTION OF THE DRAWINGS

FIGS. 1A-1C show a cross-section view, a 3D (3-dimensional) view, and a top view of a prior art lateral double diffused metal oxide semiconductor (LDMOS) device 100, respectively.

FIGS. 2A-2D show a first embodiment of the present invention.

FIG. 3 shows a second embodiment of the present invention.

FIG. 4 shows a third embodiment of the present invention.

FIG. 5 shows a fourth embodiment of the present invention.

FIG. 6 shows a fifth embodiment of the present invention.

FIG. 7 shows a sixth embodiment of the present invention.

FIG. 8 shows a seventh embodiment of the present invention.

FIG. 9 shows an eighth embodiment of the present invention.

FIG. 10 shows a ninth embodiment of the present invention.

FIG. 11 shows a tenth embodiment of the present invention.

FIGS. 12A-12C show characteristic curves of a prior art LDMOS device.

FIGS. 13A-13C show characteristic curves of an LDMOS device according to the present invention.

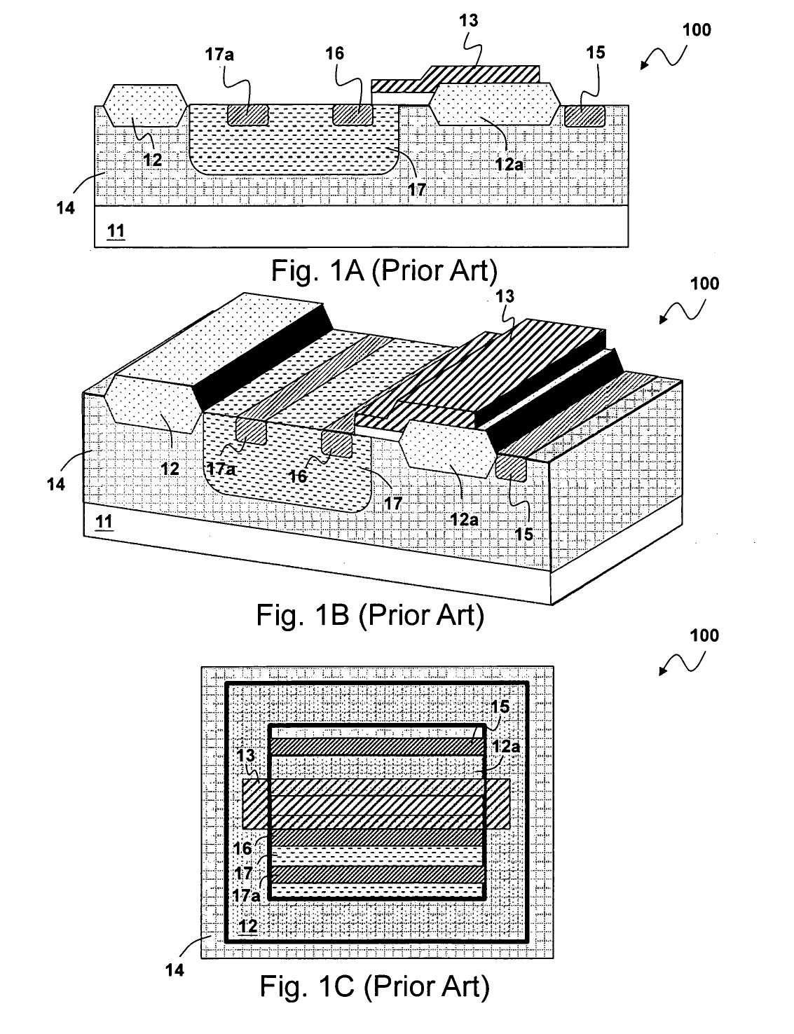

### DESCRIPTION OF THE PREFERRED EMBODIMENTS

The drawings as referred to throughout the description of the present invention are for illustration only, to show the interrelations between the regions and the process steps, but not drawn according to actual scale.

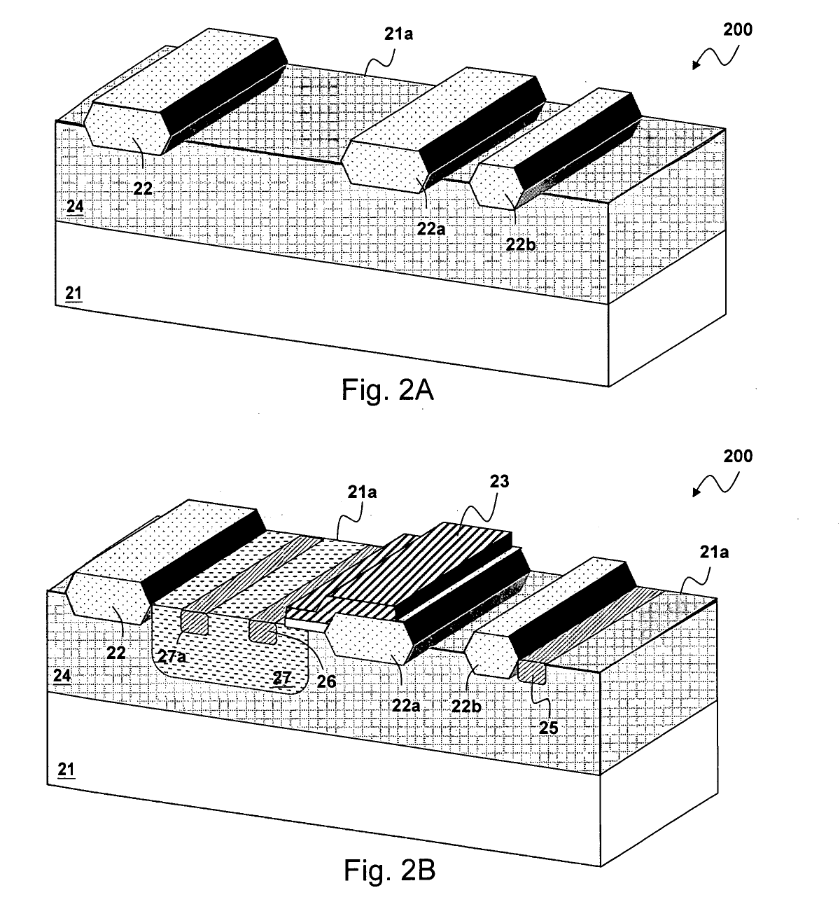

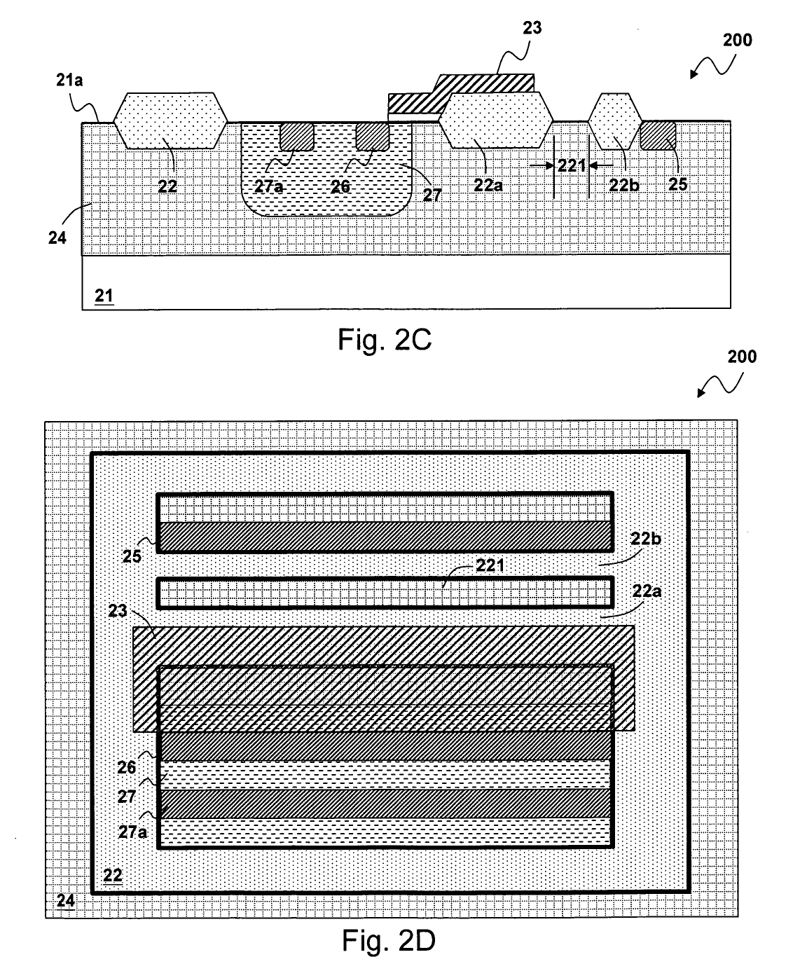

Please refer to FIGS. 2A-2D for a first embodiment according to the present invention, wherein FIGS. 2A-2B are 3D schematic diagrams showing a manufacturing method of an LDMOS device 200 according to the present invention, and FIGS. 2C and 2D are a cross-section view and a top view of the LDMOS device 200 respectively. As shown in FIGS. 2A and 2B, first, a substrate 21 with an upper surface 21a is provided, wherein the substrate 21 is for example but not limited to a P-type substrate (or an N-type substrate in another embodiment). The substrate 21 for example is a non-epitaxial silicon substrate, or an epitaxial substrate. Next, as shown in FIG. 2A, an isolation region 22 and field oxide regions 22a and 22b are formed on the upper surface 21a. The field oxide regions 22a and 22b are located in a high voltage well 24 from top view (referring to FIG. 2D), wherein the high voltage well 24 is formed in a later process step. The isolation region 22 and field oxide regions 22a and 22b are, for example, a LOCOS or an STI structure (the former being shown in FIGS. 2A-2C). The isolation region 22 and field oxide regions 22a and 22b may be formed by for example but not limited to the same process steps. Next, an N-type high voltage well 24 is formed in the substrate 21 beneath the upper surface 21a by an ion implantation process step, wherein the ion implantation process step implants N-type impurities to a defined region in the form of accelerated ions. Note that the field oxide regions 22a and 22b have masking effect to the aforementioned accelerated ions, and therefore the distribution of the N-type impurity concentration in the high voltage well 24 is related to the location of the field oxide region 22b. According to this embodiment, an opening region 221 (referring to FIGS. 2C and 2D) is defined beneath the upper surface 21a between the field oxide regions 22a and 22b, wherein the N-type impurity concentration below the opening region 221 is higher than that below the field oxide regions 22a and 22b.

Next, referring to FIGS. 2B, 2C, and 2D, a gate 23, a drain 25, a source 26, a body region 27, and a body electrode 27a are formed. As shown in FIG. 2B, the gate 23 is formed on the upper surface 21a, wherein a part of the gate 23 is above the field oxide region 22a. The drain 25 and the source 26 for example are N-type but not limited to N-type, and they are beneath the upper surface 21a and at different sides of the gate 23 in the high voltage well 24. The drain 25 and the source 26 are separated by the gate 23 and the field oxide regions 22a and 22b, as shown by the top view of FIG. 2D. The body region 27 is formed in the high voltage well 24 beneath the upper surface 21a at the same side as the source 26 with respect to the gate 23, and the source 26 is in the body region 27. The drain 25 is formed at the other side of the gate 23 in the high voltage well 24. The N-type source 26 and drain 25 are formed beneath the upper surface 21a by lithography process steps and ion implantation process steps, wherein the lithography process step defines the implantation regions by a photoresist mask together with a self-alignment effect provided by all or part of the gate 23 and the field oxide regions 22a and 22b, and the ion implantation process step implants N-type impurities to the defined regions in the form of accelerated ions. The P-type body region 27 and body electrode 27a are formed beneath the upper surface 21a by lithography process steps and ion implantation process steps, wherein the lithography process step defines the implantation regions by a photoresist mask together with a self-alignment effect provided by all or part of the gate 23 and the isolation region 22, and the ion implantation process step implants P-type impurities to the defined regions in the form of accelerated ions. The source 26 and drain 25 may be formed by the same or different lithography and ion implantation process steps, and besides, the sequence for forming the source 26, the drain 25, the body region 27, and the body electrode 27a can be any order.

In the prior art LDMOS device 100, the drift region between the body region 17 and the drain 15 is entirely covered by the gate 13 and the field oxide region 12a from top view. This embodiment is different from the prior art LDMOS device 100 in that, the drift region of the LDMOS device 200 in this embodiment is not entirely covered by the gate 23 and the field oxide regions 22a and 22b. Part of the upper surface 21a between the field oxide regions 22a and 22b above the drift region is exposed, such that the ion implantation process step which forms the high voltage well 24 implants more impurities in the opening region 221, and therefore, the N-type impurity concentration below the opening region 221 is higher than that below the field oxide regions 22a and 22b. This arrangement is advantageous over the prior art in that: First, the LDMOS device of the present invention has a relatively higher breakdown voltage, in particular a relatively higher ON breakdown voltage because the Kirk effect is mitigated according to the present invention. Second, in manufacturing process, no additional process step or mask is required, that is, the field oxide region 22b may be formed by the same process steps with the field oxide region 22a and the isolation region 22 without any additional process step. As such, the LDMOS device in the present invention has a higher breakdown voltage while it can be manufactured by a low cost.

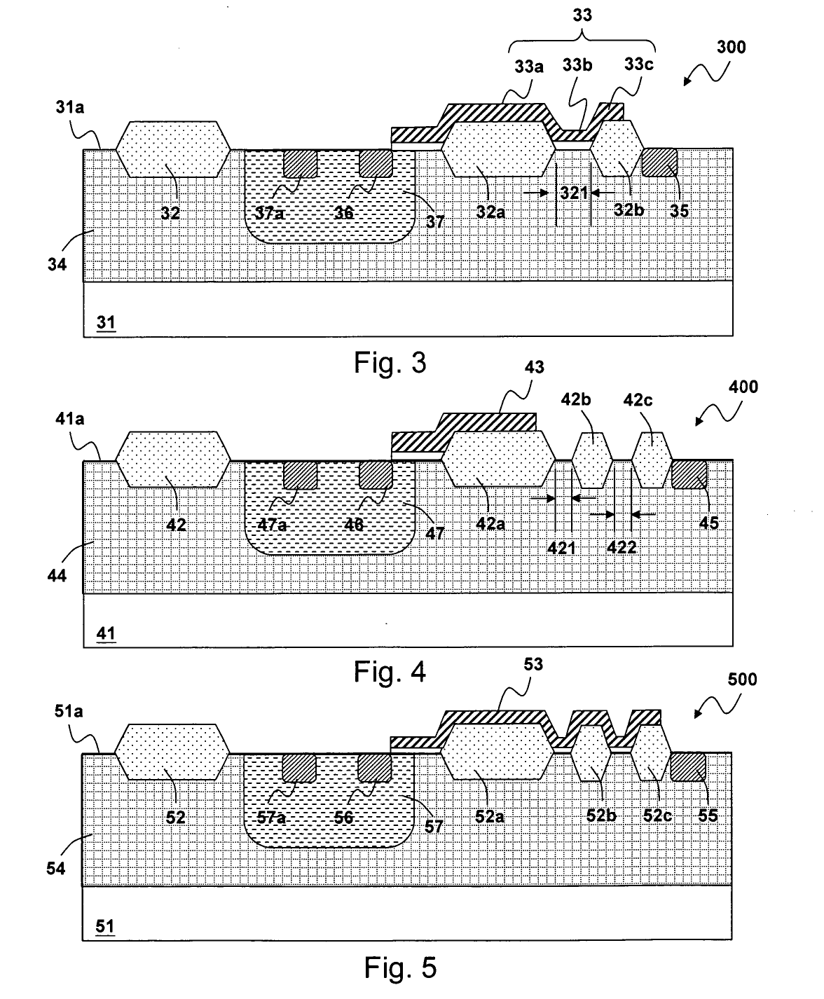

FIG. 3 shows a second embodiment of the present invention. FIG. 3 is a schematic diagram showing a cross-section view of an LDMOS device 300 of the present invention. The LDMOS device 300 is formed in a substrate 31 and includes a device region defined by an isolation region 32. The LDMOS device 300 includes field oxide regions 32a and 32b, a gate 33, a high voltage well 34, a drain 35, a source 36, a body region 37, and a body electrode 37a. This embodiment is different from the first embodiment in that, as shown in FIG. 3, the gate 33 includes a first part 33a above the field oxide region 32a, a second part 33b above the opening region 321 of the upper surface 31a, and a third part 33c above the field oxide region 32b. Note that the second part 33b preferably includes a gate dielectric layer (i.e., the gate 33 includes a gate electrode and a gate dielectric layer), and the gate dielectric layer is connected to the upper surface 31a to prevent direct electrical connection between the gate electrode and the high voltage well 34. In another embodiment of the present invention, the gate 33 does not have to include the third part 33c.

FIG. 4 shows a third embodiment of the present invention. FIG. 4 is a schematic diagram showing a cross-section view of an LDMOS device 400 of the present invention. The LDMOS device 400 is formed in a substrate 41 and includes a device region defined by an isolation region 42. The LDMOS device 400 includes field oxide regions 42a, 42b, and 42c, a gate 43, a high voltage well 44, a drain 45, a source 46, a body region 47, and a body electrode 47a. This embodiment is different from the first embodiment in that, as shown in FIG. 4, the LDMOS device 400 includes multiple field oxide regions 42b and 42c between the field oxide region 42a and the drain 45. Multiple opening regions are defined between the field oxide region 42a and its adjacent field oxide region 42b, and between the field oxide regions 42b and 42c, as indicated by the opening regions 421 and 422 shown in the figure. The N-type impurity concentrations below the upper surface 41a within the opening regions 421 and 422 are higher than those below the field oxide regions 42a, 42b, and 42c.

FIG. 5 shows a fourth embodiment of the present invention. FIG. 5 is a schematic diagram showing a cross-section view of an LDMOS device 500 of the present invention. The LDMOS device 500 is formed in a substrate 51 and includes a device region defined by an isolation region 52. The LDMOS device 500 includes field oxide regions 52a, 52b, and 52c, a gate 53, a high voltage well 54, a drain 55, a source 56, a body region 57, and a body electrode 57a. This embodiment is different from the third embodiment in that, similar to the second embodiment, as shown in FIG. 5, the gate 53 covers field oxide regions 52a, 52b, and 52c, and multiple opening regions between these field oxide regions. Certainly, the part of the gate 53 above the opening regions preferably includes a gate dielectric layer (i.e., the gate 53 includes a gate electrode and a gate dielectric layer), and the gate dielectric layer is connected to the upper surface 51a to prevent direct electrical connection between the gate electrode and the high voltage well 54.

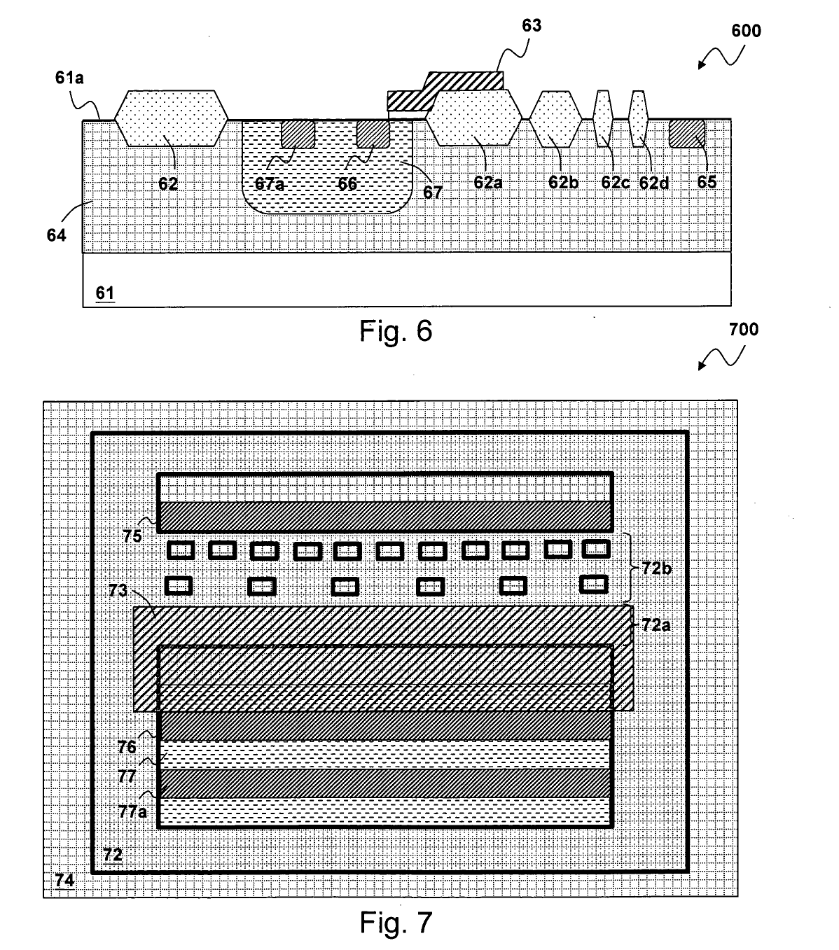

FIG. 6 shows a fifth embodiment of the present invention. FIG. 6 is a schematic diagram showing a cross-section view of an LDMOS device 600 of the present invention. As shown in FIG. 6, the LDMOS device 600 is formed in a substrate 61 and includes a device region defined by an isolation region 62. The LDMOS device 600 includes field oxide regions 62a, 62b, 62c, and 62d, a gate 63, a high voltage well 64, a drain 65, a source 66, a body region 67, and a body electrode 67a. This embodiment intends to show that in the LDMOS device 600 according to the present invention, the distribution of the N-type impurity concentration below the opening regions maybe adjusted by providing different-sized field oxide regions 62a, 62b, 62c, and 62d, such that the characteristics of the LDMOS device according to the present invention may be optimized. For example, the opening region relatively nearer to the drain 65 may have a larger area than that of the opening region relatively nearer to the field oxide region 62a, to obtain an optimized ON breakdown voltage. For another example, the field oxide region relatively nearer to the drain 65 may have a smaller size than that of the field oxide region relatively nearer to the source region 66, as shown by this cross section view which crosses the opening regions.

FIG. 7 shows a sixth embodiment of the present invention. FIG. 7 is a schematic diagram showing a top view of an LDMOS device 700 of the present invention. As shown in FIG. 7, the LDMOS device 700 includes a device region defined by an isolation region 72. The LDMOS device 700 includes field oxide regions 72a and 72b, a gate 73, a high voltage well 74, a drain 75, a source 76, a body region 77, and a body electrode 77a. This embodiment intends to show that in the LDMOS device 700 according to the present invention, the field oxide region 72b may include multiple opening regions, and these opening regions may be formed at different locations with different densities, such that the breakdown voltage of the LDMOS device is increased. Different layout arrangement of the opening regions in the field oxide region 72b is also within the scope of the present invention.

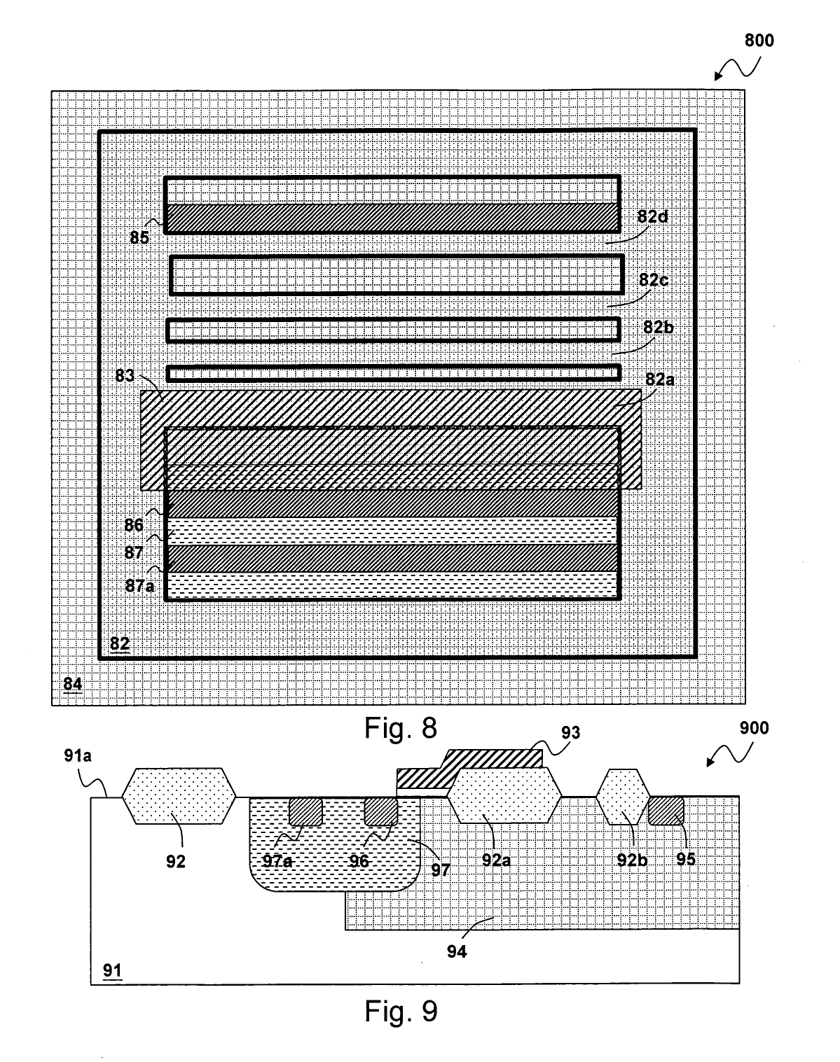

FIG. 8 shows a seventh embodiment of the present invention. FIG. 8 is a schematic diagram showing a top view of an LDMOS device 800 of the present invention. As shown in FIG. 8, the LDMOS device 800 includes a device region defined by an isolation region 82. The LDMOS device 800 includes field oxide regions 82a, 82b, 82c, and 82d, a gate 83, a high voltage well 84, a drain 85, a source 86, a body region 87, and a body electrode 87a. This embodiment intends to show that in the LDMOS device 800 according to the present invention, widths of the opening regions may be determined according to different requirements by arranging the locations and sizes of the field oxide regions 82a, 82b, 82c, and 82d.

FIG. 9 shows an eighth embodiment of the present invention. FIG. 9 is a schematic diagram showing a cross-section view of an LDMOS device 900 of the present invention. As shown in FIG. 9, the LDMOS device 900 is formed in a substrate 91 and includes a device region defined by an isolation region 92. The LDMOS device 900 includes field oxide regions 92a and 92b, a gate 93, a high voltage well 94, a drain 95, a source 96, a body region 97, and a body electrode 97a. This embodiment is different from the first embodiment. In the first embodiment, the body region 27 and the substrate 21 are separated by the high voltage well 24 such that the body region 27 is not in direct contact to the substrate 21, and therefore the LDMOS device 200 may be used, for example, as a high side device in a power supply circuit. On the other hand, as shown in the figure, part of the body region 97 of this embodiment is directly connected to the substrate 91, such that the body region 97 is electrically connected to the substrate 91, and therefore the LDMOS device 900 may be used, for example, as a low side device in a power supply circuit.

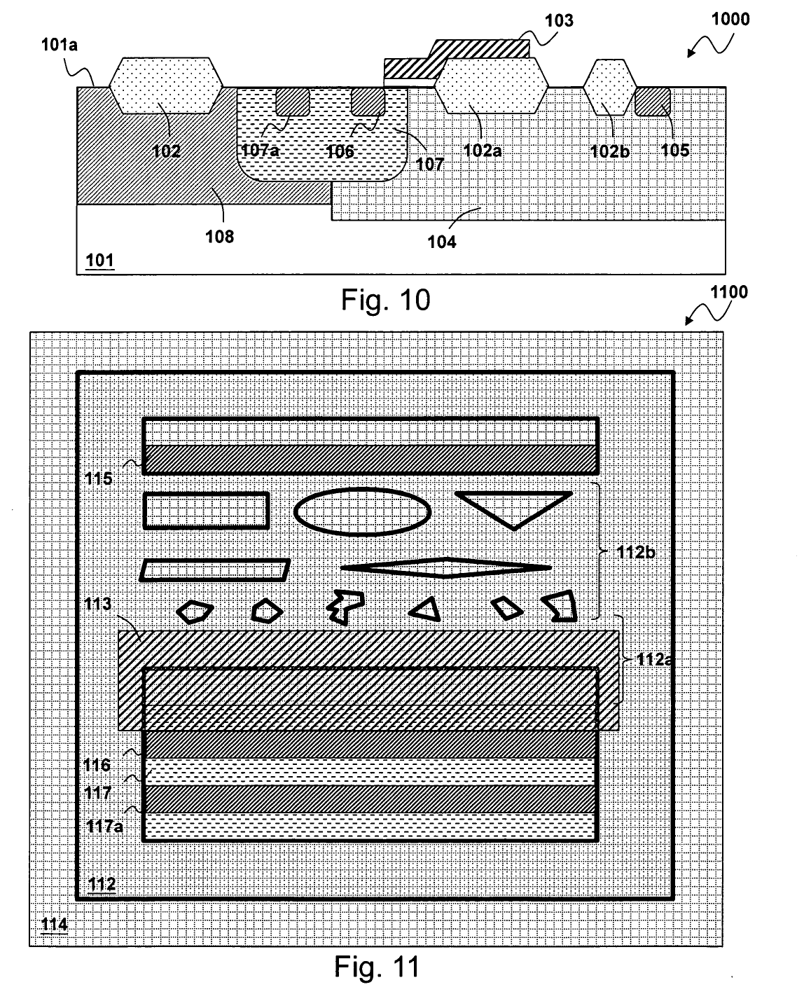

FIG. 10 shows a ninth embodiment of the present invention. FIG. 10 is a schematic diagram showing a cross-section view of an LDMOS device 1000 of the present invention. As shown in FIG. 10, the LDMOS device 1000 is formed in a substrate 101 and includes a device region defined by an isolation region 102. The LDMOS device 1000 includes field oxide regions 102a and 102b, a gate 103, a high voltage well 104, a drain 105, a source 106, a body region 107, and a body electrode 107a. Different from the eighth embodiment, part of the body region 107 of this embodiment is connected to a P-type connecting well 109 and the P-type connecting well 109 is further connected to the substrate 101, such that the body region 107 is electrically but indirectly connected to the substrate 101, and therefore the LDMOS device 1000 may be used as a low side device in a power supply circuit.

FIG. 11 shows a tenth embodiment of the present invention. FIG. 11 is a schematic diagram showing a top view of an LDMOS device 1100 of the present invention. As shown in FIG. 11, the LDMOS device 1100 includes a device region defined by an isolation region 112. The LDMOS device 1100 includes field oxide regions 112a and 112b, a gate 113, a high voltage well 114, a drain 115, a source 116, a body region 117, and a body electrode 117a. This embodiment intends to show that in the LDMOS device 1100 according to the present invention, the field oxide region 72b may include multiple opening regions, and these opening regions may have different shapes. The shape of the opening region from top view is not limited; any shape of the opening region from top view is within the scope of the present invention.

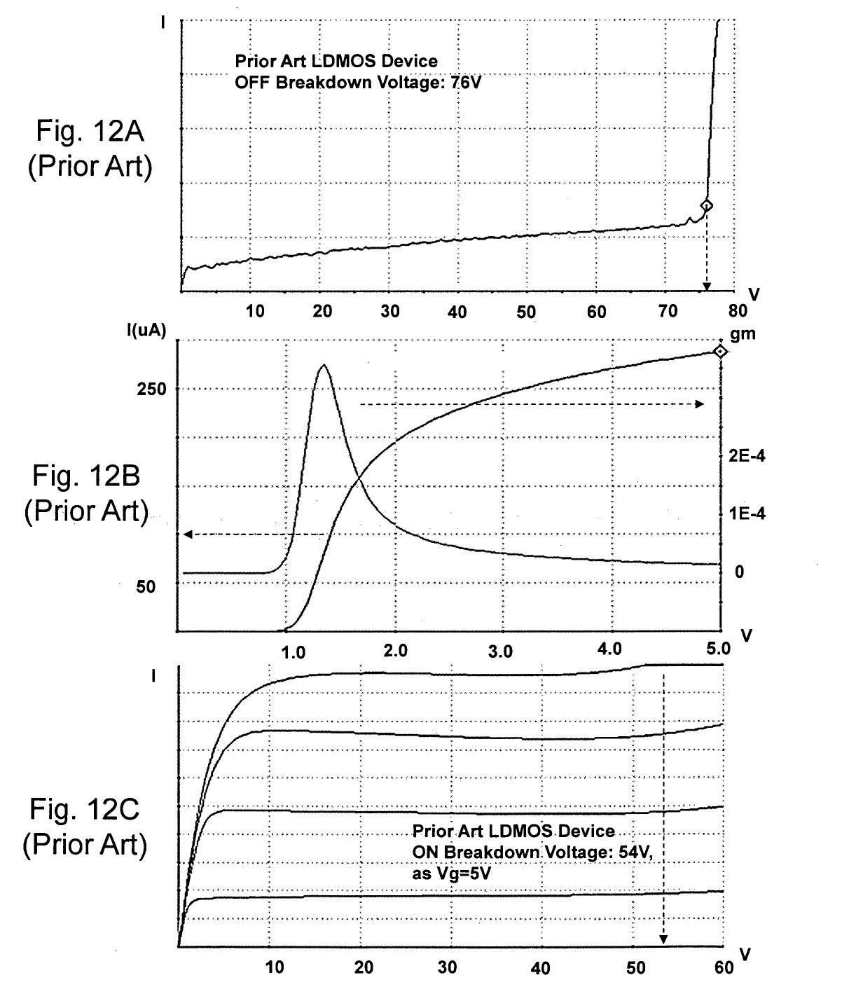

FIGS. 12A-12C show characteristic curves of a prior art LDMOS device. FIG. 12A shows a characteristic curve of a drain current Id versus a drain voltage Vd of the prior art LDMOS device in the OFF operation. The breakdown voltage of the prior art LDMOS device in the OFF operation is around 76V, as indicated by the dash line shown in the figure. FIG. 12B shows characteristic curves of the drain current Id (left vertical axis) and conductance (right vertical axis) versus a gate voltage Vg. The threshold voltage of the prior art LDMOS device is around 1V. FIG. 12C shows a characteristic curve of the drain current Id versus the drain voltage Vd of the prior art LDMOS device in the ON operation. The breakdown voltage of the prior art LDMOS device in the ON operation is around 54V, as indicated by the dash line shown in the figure.

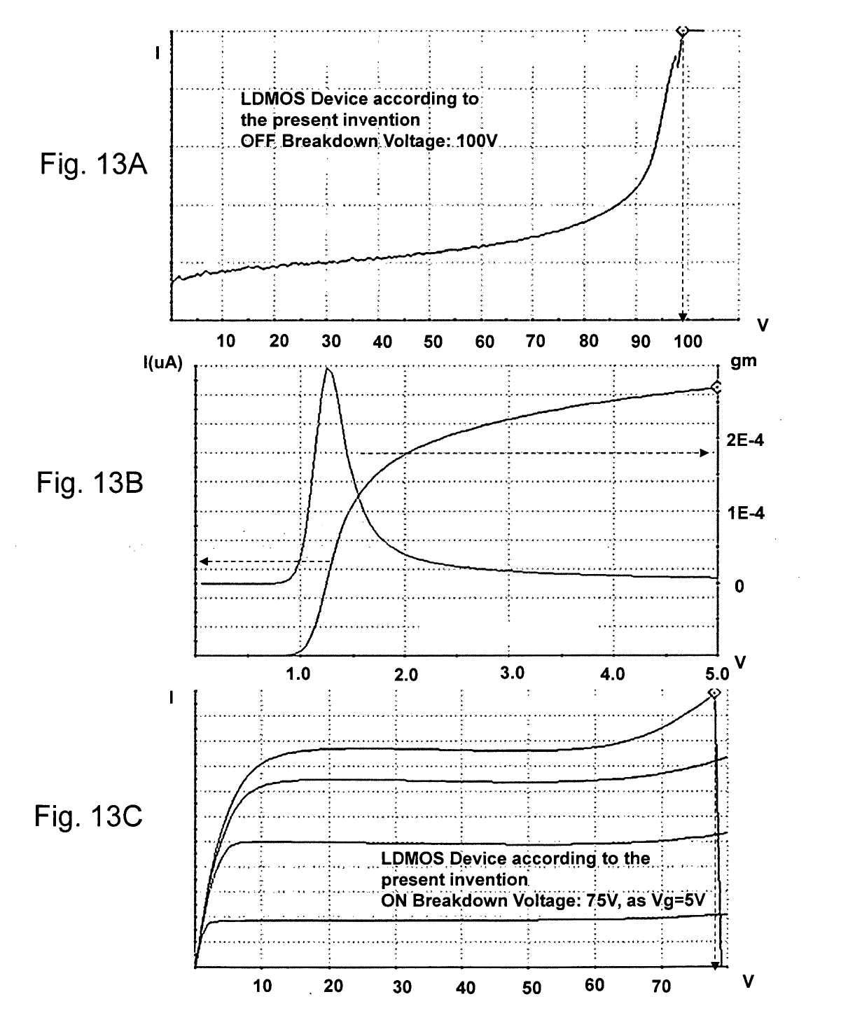

FIGS. 13A-13C show characteristic curves of an LDMOS device according to the present invention, wherein the operation voltage is the same as the LDMOS device shown in FIGS. 12A-12C. FIG. 13A shows a characteristic curve of a drain current Id versus a drain voltage Vd of the LDMOS device according to the present invention in the OFF operation. The breakdown voltage of the LDMOS device according to the present invention in the OFF operation is around 100V, as indicated by the dash line shown in the figure. FIG. 13B shows characteristic curves of the drain current Id (left vertical axis) and conductance (right vertical axis) versus a gate voltage Vg. The threshold voltage of the LDMOS device according to the present invention is around 1V, and the conductance is comparable to the prior art LDMOS device shown in FIG. 12B. FIG. 13C shows a characteristic curve of the drain current Id versus the drain voltage Vd of the LDMOS device according to the present invention in the ON operation. The breakdown voltage of the LDMOS device according to the present invention in the ON operation is around 75V, as indicated by the dash line shown in the figure.

According to the characteristic curves shown in FIGS. 12A-12C and 13A-13C of the prior art and the present invention respectively, the LDMOS device according to the present invention enhances the breakdown voltage without sacrificing the conductance.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristic of the device, such as a threshold voltage adjustment region, etc., can be added; for another example, the lithography step described in the above can be replaced by electron beam lithography, X-ray lithography, etc.; for another example, the shape of the LDMOS device from top view according to the present invention is not limited to rectangular, it may be circular or serpent. In view of the foregoing, the spirit of the present invention should cover all such and other modifications and variations, which should be interpreted to fall within the scope of the following claims and their equivalents.

1. A lateral double diffused metal oxide semiconductor (LDMOS) device formed in a first conductive type substrate, wherein the substrate has an upper surface, the LDMOS device comprising:
a second conductive type high voltage well, which is formed in the substrate beneath the upper surface;
a first field oxide region, which is formed on the upper surface, and is located in the high voltage well from top view;
a gate, which is formed on the upper surface, wherein a first part of the gate is above the first field oxide region;
a second conductive type source and a second conductive type drain, which are formed beneath the upper surface at two sides of the gate respectively;
a first conductive type body region, which is formed in the substrate beneath the upper surface, at the same side as the source with respect to the gate, wherein the source is located in the body region; and
at least one second field oxide region, which is formed on the upper surface, and is located between the first field oxide region and the drain from top view.

2. The LDMOS device of claim 1, wherein at least one opening region is defined between the first field oxide region and the at least one second field oxide region, wherein a second conductive type impurity concentration beneath the upper surface at the opening region is higher than that beneath the first field oxide region and that beneath the second oxide region.

3. The LDMOS device of claim 2, wherein the gate further includes a second part, which is formed on the upper surface at the opening region, and has a gate dielectric layer connected to the upper surface.

4. The LDMOS device of claim 3, wherein the gate further includes a third part, which is formed on the second field oxide region.

5. The LDMOS device of claim 1, wherein the LDMOS device includes a plurality of second field oxide regions, wherein a plurality of opening regions are defined between the first field oxide region and its adjacent second field oxide region, and between the second field oxide regions, wherein second conductive type impurity concentrations beneath the upper surface at the opening regions are higher than those beneath the first field oxide region and the second oxide regions.

6. The LDMOS device of claim 5, wherein the opening region which is relatively nearer to the drain has an area larger than that of the opening region which is relatively nearer to the first field oxide region.

7. The LDMOS device of claim 5, wherein the field oxide region relatively nearer to the drain has a smaller size than that of the field oxide region relatively nearer to the source region in a cross section view crossing at least one of the opening regions.

8. The LDMOS device of claim 1, wherein the body region and the substrate are separated by the high voltage well, such that the body region and the substrate are not directly in contact with each other.

9. The LDMOS device of claim 1, wherein at least part of the body region is directly connected to the substrate, or is indirectly connected to the substrate by a first conductive type connecting well, such that the body region and the substrate are electrically connected.

10. A manufacturing method of a lateral double diffused metal oxide semiconductor (LDMOS) device, comprising:
providing a first conductive type substrate, wherein the substrate has an upper surface;
forming a first field oxide region and at least one second field oxide region on the upper surface;
forming a second conductive type high voltage well in the substrate beneath the upper surface, the first field oxide region and the at least one second field oxide region being within the high voltage well from top view;
forming a gate on the upper surface, wherein the gate includes a first part, which is above the first field oxide region; and
forming a second conductive type source and a second conductive type drain beneath the upper surface at two sides of the gate respectively, and forming a first conductive type body region in the substrate beneath the upper surface, at the same side as the source with respect to the gate, wherein the source is located in the body region, and the drain is located outside the one second field oxide region or one of the second field oxide regions which is most away from the gate;
wherein the high voltage well is formed after the first and second field oxide regions are formed, such that a distribution of the concentration of the second conductive type impurities in the high voltage well is related to the location of the at least one second field oxide region.

11. The manufacturing method of claim 10, wherein at least one opening region is defined between the first field oxide region and the second field oxide region, wherein the second conductive type impurity concentration beneath the upper surface at the opening region is higher than that beneath the first field oxide region and that beneath the second oxide region.

12. The manufacturing method of claim 11, wherein the gate further includes a second part, which is formed on the upper surface at the opening region, and has a gate dielectric layer connected to the upper surface.

13. The manufacturing method of claim 12, wherein the gate further includes a third part, which is formed on the second field oxide region.

14. The manufacturing method of claim 9, wherein the LDMOS device includes a plurality of second field oxide regions, wherein a plurality of opening regions are defined between the first field oxide region and its adjacent second field oxide region, and between the second field oxide regions, wherein the second conductive type impurity concentrations beneath the upper surface at the opening regions are higher than those beneath the first field oxide region and the second oxide regions.

15. The manufacturing method of claim 14, wherein the opening region which is relatively nearer to the drain has an area larger than that of the opening region which is relatively nearer to the first field oxide region.

16. The manufacturing method of claim 14, wherein the field oxide region relatively nearer to the drain has a smaller size than that of the field oxide region relatively nearer to the source region in a cross section view crossing at least one of the opening regions.

17. The manufacturing method of claim 9, wherein the body region and the substrate are separated by the high voltage well, such that the body region and the substrate are not in direct contact with each other.

18. The manufacturing method of claim 9, wherein at least part of the body region is directly connected to the substrate, or is indirectly connected to the substrate by a first conductive type connecting well, such that the body region and the substrate are electrically connected.
